(19) United States
(12) Patent Application Publication
(10) Pub. No.: US 2024/0312796 A1
(43) Pub. Date: Sep. 19, 2024

(54) ORGANIC INTERPOSER STRUCTURE, MANUFACTURING METHOD AND PACKAGE STRUCTURE THEREOF

(71) Applicant: Zhuhai ACCESS Semiconductor Co., Ltd, Guangdong (CN)

(72) Inventors: XIANMING CHEN, Guangdong (CN); YEJIE HONG, Guangdong (CN); GAO HUANG, Guangdong (CN); BENXIA HUANG, Guangdong (CN); XIAOWEI XU, Guangdong (CN)

(21) Appl. No.: 18/603,347

(22) Filed: Mar. 13, 2024

(30) Foreign Application Priority Data
Mar. 14, 2023 (CN) 2023102473507

(51) Int. Cl. H01L 21/48; H01L 21/683; H01L 23/00; H01L 23/538

(52) U.S. Cl. CPC H01L 21/4857; H01L 21/6835; H01L 23/5383; H01L 24/16; H01L 2221/68345; H01L 2224/16227

(57) ABSTRACT

A manufacturing method for an organic interposer structure includes (a) providing a bearing plate, (b) applying a temporary bonding layer on the bearing plate, (c) applying a photosensitive dielectric layer on the temporary bonding layer, (d) forming a window on the photosensitive dielectric layer and performing metallization to form a circuit layer, (e) repeating the steps (c) and (d) on the circuit layer until the target number of layers is achieved, (f) de-bonding the temporary bonding layer and removing the bearing plate to expose the conducting post, (g) thinning the exposed conducting post to form a first pad, forming a solder mask layer on the surface of the outermost exposed circuit layer, wherein the solder mask layer exposes part of the circuit layer to form a second pad, and (h) performing a metal surface treatment on the first and second pads.

### CROSS-REFERENCE TO RELATED APPLICATION AND CLAIM OF PRIORITY

This application claims the benefit under 35 USC § 119 of Chinese Patent Application No. 2023102473507, filed on Mar. 14, 2023, in the China Intellectual Property Office, the entire disclosure of which is incorporated herein by reference for all purposes.

### BACKGROUND

### 1. TECHNICAL FIELD

The present disclosure relates to the field of semiconductor technology, and more particularly, to an organic interposer structure, a manufacturing method, and a package structure thereof.

### 2. BACKGROUND

As Moore's law slows down, advanced package techniques become one of the key factors driving further improvements in chip performance and enabling higher-density integration of semiconductor package structures. Recently, various advanced packaging techniques have been proposed and widely used, such as 2D package, 2.5D package, etc.

### SUMMARY

In view of the above, it is an object of the present disclosure to provide an organic interposer structure, a manufacturing method, and a package structure thereof.

In view of the above objects, in a first aspect, the present disclosure provides a method for manufacturing an organic interposer structure, including:
(a) providing a bearing plate;
(b) applying a temporary bonding layer on the bearing plate;
(c) applying a photosensitive dielectric layer on the temporary bonding layer;
(d) forming a window on the photosensitive dielectric layer and performing metallization to form a circuit layer, wherein the window forms a conducting post;
(e) repeating the steps (c) and (d) on the circuit layer until the target number of layers is achieved;
(f) de-bonding the temporary bonding layer, and removing the bearing plate to expose the conducting post;
(g) thinning the exposed conducting post to form a first pad; forming a solder mask layer on the surface of the outermost exposed circuit layer, wherein the solder mask layer exposes part of the circuit layer to form a second pad; and
(h) performing metal surface treatment on the first pad and the second pad.

In some embodiments, the bearing plate is made of glass or acrylic.

In some embodiments, the bearing plate has a thickness of 200-1000 μm.

In some embodiments, the material of the temporary bonding layer is selected from an ultraviolet decomposed adhesive tape, a pyrolytic adhesive tape, and a weak adhesive tape.

In an embodiment, the step (c) includes:
applying a photosensitive dielectric material on the temporary bonding layer to form an organic photosensitive dielectric layer; and
forming a window on the organic photosensitive dielectric layer by means of exposure and development.

In some embodiments, the step (d) includes:
applying a metal seed layer on the photosensitive dielectric layer;
applying a photoresist layer on the surface of the metal seed layer and forming a circuit layer pattern by exposure and development;
electroplating the circuit layer pattern to form the conducting post and the circuit layer;
removing the photoresist layer; and
etching the exposed metal seed layer.

In some embodiments, the metal surface treatment in the step (h) includes OSP, ENEPIG, or BGA.

In some embodiments, the solder mask layer is a photosensitive dielectric material.

In some embodiments, the first pad is configured to connect to a chip and the second pad is configured to connect to a package substrate.

In a second aspect, the present disclosure provides an organic interposer structure, including:
a redistribution layer including at least two stacked distribution units, wherein each distribution unit includes a dielectric layer and a circuit layer on the dielectric layer, and the dielectric layer is provided with the conducting post conductively connected to the circuit layer;
a solder mask layer covering the circuit layer on the surface of the redistribution layer; and
a first pad formed by a conducting post exposed on the surface of the redistribution layer and a second pad formed by a circuit layer exposed on the solder mask layer, wherein a height of the first pad is lower than a height of the dielectric layer.

In some embodiments, the first pad is configured to connect to a chip and the second pad is configured to connect to a package substrate.

In some embodiments, the solder mask layer is a photosensitive dielectric material.

In a third aspect, the present disclosure provides a package structure including the organic interposer structure of any of the second aspects.

In some embodiments, further including a chip and a package substrate; wherein the chip is connected to the first pad; the package substrate is connected to the second pad.

It can be seen from the above that the present disclosure provides an organic interposer structure, a manufacturing method, and a package structure thereof. By using photosensitive dielectric materials to form an organic interposer, ultra-fine circuit, and small solder mask window can be produced, which meets the requirements of a high-density I/O chip flip package while achieving low processing difficulty and cost.

### BRIEF DESCRIPTION OF THE DRAWINGS

In order to more clearly illustrate the technical solutions of the present disclosure or related art, a brief description will be given below of the accompanying drawings which are required to be used in the description of the embodiments. It is obvious that the drawings in the description below are only embodiments of the present disclosure, and it would be obvious for a person skilled in the art to obtain other drawings according to these drawings without involving any inventive effort. In the drawings, the thickness and shape of some of the layers and regions may be exaggerated for better understanding and ease of description.

FIGS. 1A-1L show schematic cross-sectional views of intermediate structures at various steps of a method for manufacturing an organic interposer structure provided by an embodiment of the present disclosure;

FIG. 2 is a structural schematic diagram of an organic interposer structure provided by an embodiment of the present disclosure; and

FIG. 3 is a structural schematic diagram of a package structure provided by an embodiment of the present disclosure.

### DETAILED DESCRIPTION OF THE EMBODIMENTS

In order to make the purpose, technical solution, and advantages of this disclosure clearer, the following is a detailed explanation of this disclosure, combined with specific embodiments and referring to the accompanying drawings.

It should be noted that unless otherwise defined, technical or scientific terms used in the embodiments of the present disclosure shall have the ordinary meaning as understood by one of ordinary skill in the art to which the present disclosure belongs. The use of “first”, “second”, and similar terms in the embodiments of the present disclosure does not denote any order, quantity, or importance, but rather is used to distinguish one element from another. The word “comprising” or “comprises”, and the like, means that the elements or items preceding the word encompass the elements or items listed after the word and equivalents thereof, but do not exclude other elements or items. “connected” or “attached” and like terms are not limited to physical or mechanical connections, but may include electrical connections, whether direct or indirect. When terms such as “on”, “above”, “below”, and “beside” are used to describe a positional relationship between two components, one or more of the components may be located between the two components unless the terms are used in conjunction with the terms “immediately” or “directly”. When an element or layer is provided “on” another element or layer, the other layer or element can be directly interposed on or between the other elements.

At present, 2D package technology is to directly integrate and package multiple different types of chips on the substrate surface, and chip interconnection is achieved through the wiring of the substrate, which has good reliability. However, the density of multiple-chip interconnection is limited by the process capability of the package substrate, and the integration density is low. In order to achieve high-density heterogeneous integration, a package substrate with a finer linewidth/linespace (L/S), a higher number of layers, and a larger unit size is required, and the substrate processing capability is difficult to match.

The 2.5D package is provided with an interposer between the package substrate and the chip, wherein the interposer realizes chip-to-chip interconnection and chip-to-package substrate interconnection via a silicon TSV. The interposer containing silicon through-holes can realize fine circuit manufacture, but it requires high processing equipment, but cannot realize large panel fabrication, and has high silicon wafer cost and high processing cost.

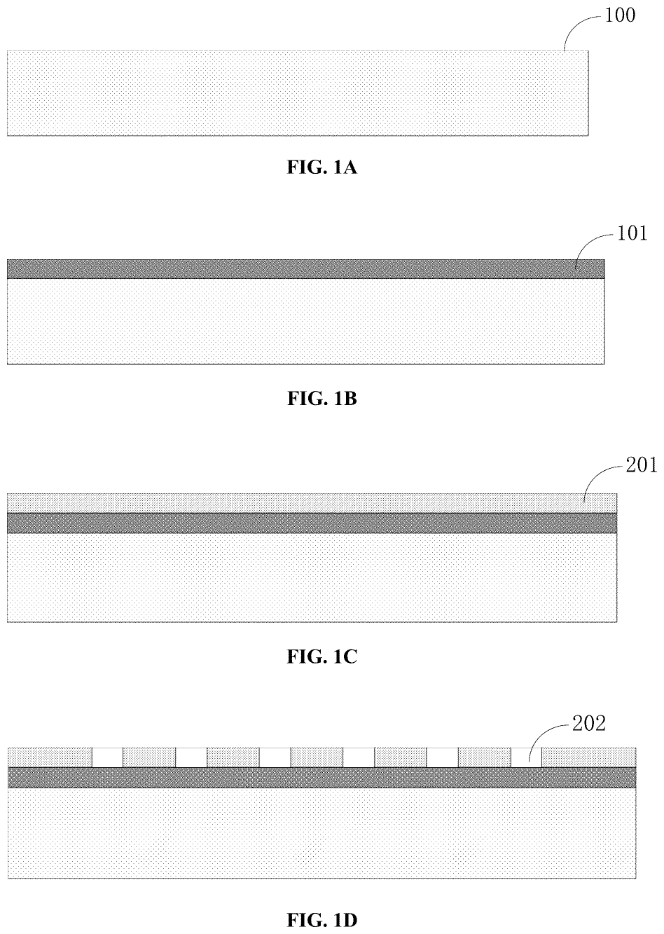

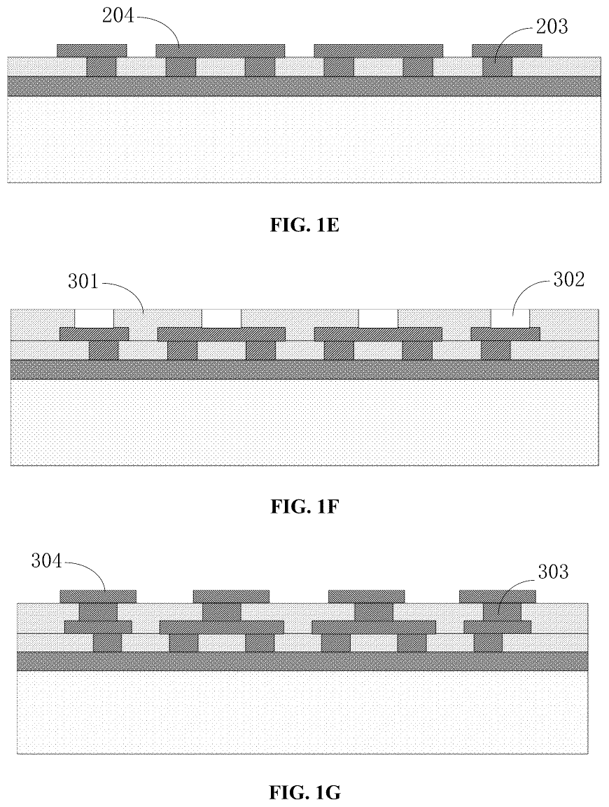

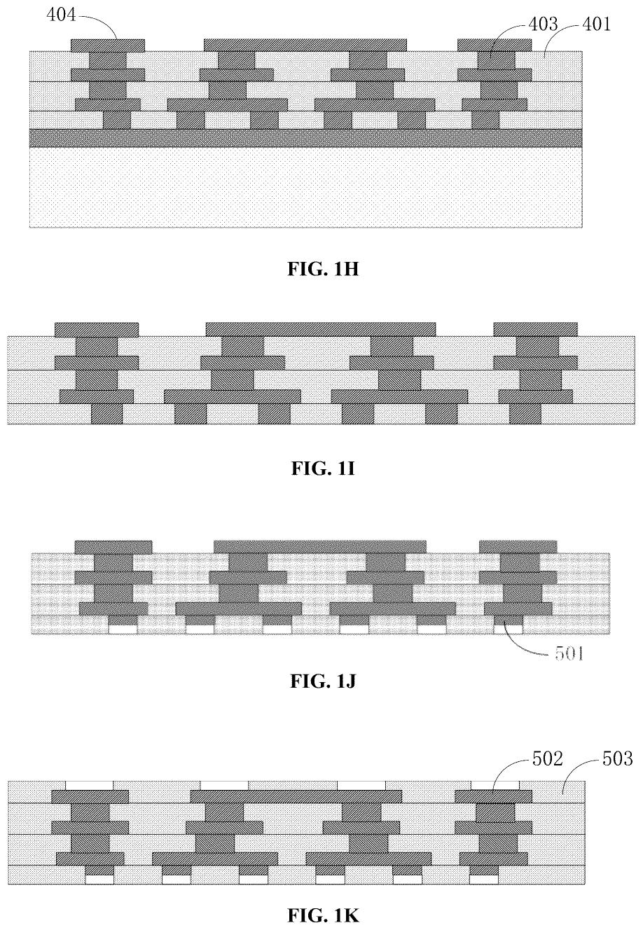

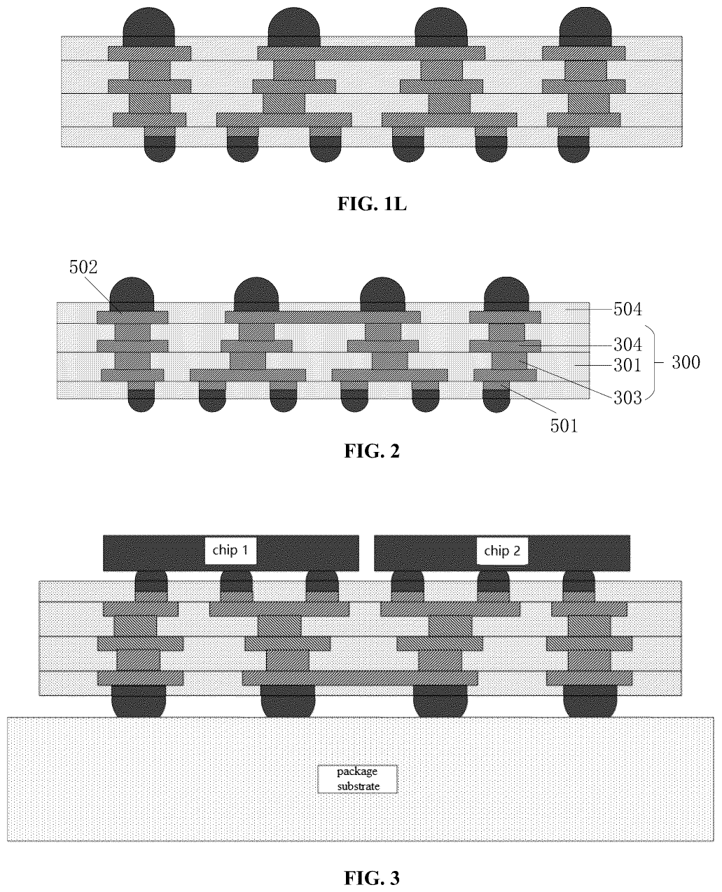

In view of this, a first aspect of embodiments of the present disclosure provides a method for manufacturing an organic interposer structure. FIGS. 1A-1L show schematic cross-sectional views of intermediate structures at various steps of a method for manufacturing an organic interposer structure provided by an embodiment of the present disclosure.

The manufacturing method includes the following steps: a bearing plate 100 is provided-step (a), as shown in FIG. 1A.

In some embodiments, the bearing plate 100 is made of glass or acrylic. The smooth surface of glass or acrylic helps to achieve ultra-fine circuit manufacture.

It should be noted that the thickness of the bearing plate 100 may be determined according to requirements, and the present disclosure is not limited thereto. Exemplary, the bearing plate 100 has a thickness of 200-1000 μm, such as 200 μm, 300 μm, 400 μm, 500 μm, 600 μm, 800 μm, and 1000 μm.

Next, a temporary bonding layer 101 is formed on the bearing plate 100-step (b), as shown in FIG. 1B. Generally, the temporary bonding layer 101 has a weak tack that can be used to bond components. After de-bonding, the tack is weakened to facilitate the removal of the bearing plate 100; the temporary bonding layer 101 may be formed by spin coating or/and coating a liquid resin or may be formed by laminating a dry film type.

Alternatively, the material of the temporary bonding layer is selected from a UV-decomposed adhesive tape, a pyrolytic adhesive tape, and a weak adhesive tape.

Then, an organic photosensitive dielectric layer 201 with windows is formed on the temporary bonding layer 101-step (c), as shown in FIGS. 1C and 1D.

In some embodiments, step (c) includes: a photosensitive dielectric material is applied on the temporary bonding layer 101 to form an organic photosensitive dielectric layer 201, as shown in FIG. 1C. Here, the organic photosensitive dielectric layer 201 may be formed by laminating or applying, and the present disclosure is not limited thereto. Next, as shown in FIG. 1D, a window 202 is formed on the organic photosensitive dielectric layer 201 by means of exposure and development. Note that the resolving power of the photosensitive dielectric material can be excellent. By way of example, a 25 μm diameter window may be formed by applying a 25 μm thick photosensitive dielectric material to facilitate the manufacture of a tiny window.

Then, a conducting post 203 is formed at the position of the window 202; and a circuit layer 204 is formed on the organic photosensitive dielectric layer 201-step (d), as shown in FIG. 1E.

As a specific embodiment, step (d) includes: a metal seed layer is applied on the organic photosensitive dielectric layer 201; then a photoresist layer is applied on the surface of the metal seed layer, and a circuit layer pattern is formed by exposure and development; then, a conducting post 203 and a circuit layer 204 are formed by electroplating; next, the photoresist layer is removed; the metal seed layer is finally etched to expose the organic photosensitive dielectric layer 201.

It should be noted that the above-mentioned embodiments are merely examples, and a person skilled in the art would have chosen an appropriate process for forming the conducting post 203 and the circuit layer 204 according to actual production conditions.

Then, steps (c) and (d) are repeated on the circuit layer until the target number of layers-step (e)-is achieved, as shown in FIGS. 1F-1H.

Hereinafter, with reference to FIGS. 1F-1H, the schemes of repeating steps (c) and (d) will be described in detail by taking the target layer of three as an example. Note that the manufacture of the first organic photosensitive dielectric layer, the first conducting post, and the first circuit layer corresponds to the organic photosensitive dielectric layer 201, the conducting post 203, and the circuit layer 204, respectively, and will not be described in detail.

A second organic photosensitive dielectric layer 301 having a second window 302 is formed by applying a photosensitive dielectric material on the first circuit layer, as shown in FIG. 1F. A second conducting post 303 is formed at the position of the window 302; a second circuit layer 304 is formed on the second organic photosensitive dielectric layer 301, as shown in FIG. 1G. In the same manner, a third photosensitive dielectric layer 401, a third conducting post 403, and a third circuit layer 404 are formed on the second circuit layer 304, as shown in FIG. 1H.

Here, the materials of the first photosensitive dielectric layer, the second photosensitive dielectric layer 301, and the third photosensitive dielectric layer 401 may be the same or different, and the present disclosure is not limited thereto.

Alternatively, the material of the first circuit layer, the second circuit layer 304, and the third circuit layer 404 may be copper. Alternatively, the material of the first conducting post 203, the second conducting post 303, and the third conducting post 403 may be copper.

Next, the temporary bonding layer 101 is de-bonded and the bearing plate 100 is removed-step (f), as shown in FIG. 1I. Note that the de-bonding manner is determined according to the material of the temporary bonding layer 101. For example, if the temporary bonding layer 101 is an ultraviolet decomposed adhesive tape, the temporary bonding layer 101 is de-bonded by irradiating ultraviolet light. In another example, the temporary bonding layer 101 is a pyrolytic adhesive tape, which is then de-bonded by heating.

Then, the exposed conducting post is thinned to form a first pad 501; a solder mask layer 503 having a window is formed on the exposed circuit layer surface to expose a portion of the circuit layer to form a second pad 502-step (g), as shown in FIGS. 1J-1K. Here, the way of thinning the conducting posts may be etching.

Alternatively, the material of the solder mask layer 503 is a photosensitive dielectric material. The manufacture of a minute solder mask window is achieved by utilizing the high resolution capability of the photosensitive dielectric material. Exemplary, the window is formed by means of exposure and development.

Finally, the surface treatment on the first pad 501 and the second pad 502 is performed for packaging a chip and a package substrate, respectively-step (h), as shown in FIG. 1L.

In some embodiments, the surface treatment in step (h) includes one or more of organic solderability preservative (OSP), electroless nickel electroless palladium immersion gold (ENEPIG), and ball grid array (BGA).

Optionally, the first pad 501 is configured to package the chip, and the second pad 502 is configured to package the package substrate. Here, the first pad 501 can realize a small size, and a small pitch, and can be applied to a flip-chip package of a plurality of high-density I/O chips.

It can be seen therefrom that the method for manufacturing the organic interposer structure of the present disclosure can achieve panel-level processing, with high processing efficiency and low processing cost. The organic interposer structure can achieve 2.5D package, with less processing difficulty and low cost compared with the silicon interposer, thereby achieving a high-density integrated package at a low cost.

In a second aspect, embodiments of the present disclosure also provide an organic interposer structure. As shown in FIG. 2, the organic interposer structure includes a redistribution layer 300, including at least two distribution units (in the present example, having three distribution units), each distribution unit including a dielectric layer 301 and a circuit layer 304 on the dielectric layer 301. The dielectric layer 301 is provided therein with a conducting post 303 for conducting a circuit layer 304. Note that the redistribution layer 300 shown in FIG. 2 is a three-layer structure. The remaining dielectric layers, circuit layers, and conducting posts are not marked in the figure. The solder mask layer 504 is located on the circuit layer on the surface of the redistribution layer 300. A first pad 501 is formed by the exposed conducting post on the surface of the redistribution layer 300 and a second pad 502 is formed by the exposed circuit layer on the solder mask layer 504, wherein the first pad 501 is formed by etching the exposed conducting post so that the height of the first pad 501 is lower than the height of the dielectric layer where it is located. Such a first pad 501 recessed in the dielectric layer may have an opening for receiving solder, and the solder of the chip terminal can be received in the fine circuit manufacture so that the first pad 501 can better fix the terminal connected to the chip so that the connection process of the chip terminal to the pad can be simplified.

In such a technical solution, the redistribution layer 300 can use an organic photosensitive dielectric material to prepare the dielectric layer 301 and thus can have a high-resolution capability, enable the manufacture of fine lines, and realize 2.5D package, with small processing difficulty and low cost.

In some embodiments, a first pad 501 is configured to connect to a chip and a second pad 502 is configured to connect to a package substrate.

In some embodiments, the material of the solder mask layer 504 is a photosensitive dielectric material, enabling the manufacture of tiny solder mask window.

In a third aspect, embodiments of the present disclosure also provide a package structure including the organic interposer structure of any of the aforementioned aspects, as shown in FIG. 3. Optionally, the package structure further includes a chip and a package substrate; wherein the chip is connected to the first pad 501; the package substrate is connected to a second pad 502. The number of chips may be plural and is not limited herein.

Those of ordinary skill in the art will appreciate that the discussion of any embodiment above is merely exemplary and is not intended to imply that the scope of the disclosure, including the claims, is limited to these examples. Combinations of features in the above embodiments, or between different embodiments, may also be made within the spirit of the present disclosure; the steps may be implemented in any order, and there may be many other variations of the different aspects of the embodiments of the present disclosure as described above, which are not provided in detail for clarity.

The disclosed embodiments are intended to embrace all such alternatives, modifications, and variances which fall within the broad scope of the appended claims. Therefore, any omissions, modifications, equivalent substitutions, improvements, etc. made within the spirit and principles of this disclosed embodiment shall be included within the scope of this disclosure.

What is claimed is:

1. A method for manufacturing an organic interposer structure, the method comprising:
(a) providing a bearing plate;
(b) applying a temporary bonding layer on the bearing plate;
(c) applying a photosensitive dielectric layer on the temporary bonding layer;
(d) forming a window on the photosensitive dielectric layer and performing metallization to form a circuit layer, wherein the window forms a conducting post;
(e) repeating the steps (c) and (d) on the circuit layer until the target number of layers is achieved;
(f) de-bonding the temporary bonding layer, and removing the bearing plate to expose the conducting post;
(g) thinning the exposed conducting post to form a first pad and forming a solder mask layer on the surface of the outermost exposed circuit layer, wherein the solder mask layer exposes part of the circuit layer to form a second pad; and
(h) performing a metal surface treatment on the first pad and the second pad.

2. The manufacturing method of claim 1, wherein the bearing plate is made of glass or acrylic.

3. The manufacturing method of claim 1, wherein the bearing plate has a thickness of 200-1000 μm.

4. The manufacturing method of claim 1, wherein the temporary bonding layer is selected from the group consisting of an ultraviolet decomposed adhesive tape, a pyrolytic adhesive tape, and a weak adhesive tape.

5. The manufacturing method of claim 1, wherein the step (c) comprises:
applying a photosensitive dielectric material on the temporary bonding layer to form the photosensitive dielectric layer; and
forming a window on the photosensitive dielectric layer by means of exposure and development.

6. The manufacturing method of claim 1, wherein the step (d) comprises:
applying a metal seed layer on the photosensitive dielectric layer;
applying a photoresist layer on the surface of the metal seed layer and forming a circuit layer pattern by exposure and development;
electroplating the circuit layer pattern to form the conducting post and the circuit layer;
removing the photoresist layer; and
etching the exposed metal seed layer.

7. The manufacturing method of claim 1, wherein the metal surface treatment in step (h) comprises organic solderability preservative (OSP), electroless nickel electroless palladium immersion gold (ENEPIG), and ball grid array (BGA).

8. The manufacturing method of claim 1, wherein the solder mask layer is a photosensitive dielectric layer.

9. The manufacturing method of claim 1, wherein the first pad is configured to connect to a chip, and the second pad is configured to connect to a package substrate.

10. An organic interposer structure comprising:
a redistribution layer comprising at least two stacked distribution units, wherein each distribution unit comprises a dielectric layer and a circuit layer on the dielectric layer, and the dielectric layer is provided with the conducting post conductively connected to the circuit layer;
a solder mask layer covering the circuit layer on the surface of the redistribution layer; and
a first pad formed by a conducting post exposed on the surface of the redistribution layer and a second pad formed by a circuit layer exposed on the solder mask layer, wherein a height of the first pad is lower than a height of the dielectric layer.

11. The organic interposer structure of claim 10, characterized in that the first pad is configured to connect to a chip, and the second pad is configured to connect to a package substrate.

12. The organic interposer structure of claim 10, wherein the solder mask layer is made of a photosensitive dielectric material.

13. A package structure comprising the organic interposer structure of claim 10.

14. The package structure of claim 13, further comprising a chip and a package substrate,
wherein the chip is connected to the first pad, and the package substrate is connected to the second pad.
